(19) United States
(12) Patent Application Publication
(10) Pub. No.: US 2012/0113601 A1
(43) Pub. Date: May 10, 2012

(54) CIRCUIT MODULE AND ELECTRONIC DEVICE INCLUDING THE SAME

(76) Inventor: Kazuhiro KOHARA, Osaka (JP)

(21) Appl. No.: 13/213,257

(22) Filed: Aug. 19, 2011

(30) Foreign Application Priority Data
Nov. 10, 2010 (JP) 2010-251494

(51) Int. Cl. H05K 7/02

(52) U.S. Cl. 361/736

(57) ABSTRACT

A circuit module is provided that is configured to allow a shield member to be securely mounted to a board. The circuit module includes a board with a mounting surface on which an electronic component is mounted and a shield member that is mounted to the board. The shield member includes a shield frame having a frame portion that is solder-joined to the mounting surface and a shield cover having a top surface portion and a side portion that is attached to the frame portion of the shield frame. Furthermore, an L-shaped slit is formed at a predetermined corner among four corners of the top surface portion of the shield cover so as to extend along two sides forming the predetermined corner.

This application is based on Japanese Patent Application No. 2010-251494 filed on Nov. 10, 2010, the contents of which are hereby incorporated by reference.

### BACKGROUND OF THE INVENTION

1. Field of the Invention

The present invention relates to a circuit module and an electronic device including the same.

2. Description of Related Art

Conventionally, a circuit module is known in which electronic components such as an IC are mounted on a board, and the electronic components mounted on the board are covered with a shield case. In this conventional circuit module, typically, the shield case is held by being mounted to the board. The mounting of the shield case to the board is achieved by, for example, solder joining using a reflow oven. Such a circuit module is disclosed in, for example, the publication of Japanese Patent No. 3714088.

In a case of the above-described conventional circuit module, however, in a reflow process for solder joining the board and the shield case to each other, the entire shield case is heated, which causes the shield case to be warped to a considerable degree. Because of this, the shield case remains warped even after it is no longer heated, which results in a solder joint failure between the board and the shield case. That is, the conventional type of circuit module presents a problem that the shield case is not securely mounted to the board.

### SUMMARY OF THE INVENTION

The present invention has been made to solve the above-described problem, and an object of the present invention is to provide a circuit module configured to allow a shield member to be securely mounted to a board, and an electronic device including the same.

In order to achieve the above-described object, a circuit module according to a first aspect of the present invention includes: a board having a mounting surface on which an electronic component is mounted; and a shield member that is mounted to the board so as to cover the electronic component. The shield member includes: a shield frame having a frame portion that has a quadrangular outer shape when seen in plan from the side of a region opposed to the mounting surface and is solder-joined to the mounting surface; and a shield cover that is disposed so as to externally cover the shield frame and has: a top surface portion having a quadrangular outer shape when seen in plan from the side of the region opposed to the mounting surface; and a side portion that is provided in a standing manner on the outer periphery of the top surface portion and is attached to the frame portion of the shield frame. Furthermore, when seen in plan from the side of the region opposed to the mounting surface, an L-shaped slit is formed at a predetermined corner among four corners of the top surface portion of the shield cover so as to extend along two sides forming the predetermined corner.

In the circuit module according to the first aspect, using the above-described shield member (member composed of the shield frame and the shield cover), the frame portion of the shield frame is solder-joined to the mounting surface of the board, the shield cover is disposed so as to externally cover the shield frame, and the side portion of the shield cover is attached to the frame portion of the shield frame, so that there can be brought about a state where the shield member is mounted to the board.

In this case, since the shield frame is a skeleton structural body without a large-area plate-shaped portion (portion vulnerable to warping), even if the shield frame is heated in a manufacturing process of the circuit module (or a process of solder joining the circuit module to another board), the shield frame is hardly warped. Needless to say, it is also hardly likely that the shield frame is warped after it is no longer heated (at the time the shield frame is cooled).

Furthermore, since the L-shaped slit is formed at a predetermined corner among the four corners of the top surface portion of the shield cover so as to extend along two sides forming the predetermined corner, even if the shield cover is heated in the manufacturing process of the circuit module (or a process of solder-joining the circuit module to another board), a temperature difference between the top surface portion of the shield cover and the side portion thereof is prevented from becoming so large, so that warping of the shield cover is suppressed to a reduced degree. This can prevent the shield cover from remaining warped after it is no longer heated (at the time the shield cover is cooled). Thus, even though the side portion of the shield cover is attached to the frame portion of the shield frame, in no case is the frame portion of the shield frame subjected to a strong pulling force in a direction away from the mounting surface of the board.

Moreover, with the L-shaped slit formed at a predetermined corner of the top surface portion of the shield cover so as to extend along two sides forming the predetermined corner, the top surface portion of the shield cover is made partially discontinuous with the side portion of the shield cover. Thus, the following is also achieved. That is, even if the top surface portion of the shield cover is warped, the side portion of the shield cover (frame portion of the shield frame to which the side portion of the shield cover is attached) is prevented from floating under the influence of the warping of the top surface portion of the shield cover.

As a result of the foregoing facts, a solder joint failure between the mounting surface of the board and the frame portion of the shield frame can be avoided. That is, the shield member can be securely mounted to the board.

In addition to the above, the circuit module according to the first aspect uses the above-described shield member (member composed of the shield frame and the shield cover) and thus eliminates the need to actually solder-join the shield cover for covering the electronic component to the board. That is, even after the shield member has been mounted to the board, the shield cover per se can be easily detached. Thus, for example, in a case where checking for a mounting failure such as a missing electronic component or a short circuit should be performed after the shield member has been mounted to the board, the checking for a mounting failure can be facilitated. Since the shield frame is a skeleton structural body, the checking for a mounting failure can be performed through interstices of a framework of the skeleton structural body. Accordingly, there is no need to detach the shield frame in this case.

In the circuit module according to the first aspect, preferably, the L-shaped slit is formed at each of all the four corners of the top surface portion of the shield cover. According to this configuration, warping of the shield cover can be suppressed to a further reduced degree.

In the circuit module according to the first aspect, preferably, a fitting portion is provided at each of the frame portion of the shield frame and the side portion of the shield cover, and the fitting portion provided at the frame portion of the shield frame and the fitting portion provided at the side portion of the shield cover are fitted to each other. According to this configuration, there is brought about a state where the shield cover is securely attached to the shield frame.

In the configuration in which the fitting portion is provided at each of the frame portion of the shield frame and the side portion of the shield cover, preferably, the fitting portion provided at the frame portion of the shield frame is a fitting protrusion, and the fitting portion provided at the side portion of the shield cover is a fitting hole. According to this configuration, it is only required to insert the fitting protrusion at the frame portion of the shield frame into the fitting hole at the side portion of the shield cover, and thus an operation of attaching the shield cover to the shield frame is facilitated. Needless to say, an operation of detaching the shield cover from the shield frame is also facilitated.

In the circuit module according to the first aspect, preferably, the board is a multilayer wiring board, and if a predetermined wiring layer is present that is routed in such a manner as to traverse a solder joint part to which the frame portion of the shield frame is solder-joined, instead of an uppermost wiring layer provided on the mounting surface, a wiring layer lying under the uppermost wiring layer is used as the predetermined wiring layer. According to this configuration, there is no need to form a cutout (opening) for routing the predetermined wiring layer at the frame portion of the shield frame, and thus the frame portion of the shield frame can be solder-joined around the entire periphery thereof to the mounting surface of the board. This reinforces the solder joint between the mounting surface of the board and the frame portion of the shield frame and thus makes it even more unlikely that the shield frame is warped.

In the circuit module according to the first aspect, preferably, the shield frame further includes a beam portion that is provided in such a manner as to stride across a region enclosed by the frame portion of the shield frame. According to this configuration, the shield frame that is highly rigid and unlikely to be warped can be easily obtained.

In the configuration in which the shield frame further includes the beam portion, preferably, a predetermined part of the beam portion of the shield frame is made to extend toward the mounting surface so as to stand within the plane of the mounting surface. According to this configuration, without the need to separately prepare a member to be used as a shield wall, there can be brought about a state where the shield wall (predetermined part of the beam portion of the shield frame) stands within the plane of the mounting surface of the board.

In the configuration in which the predetermined part of the beam portion of the shield frame is used as the shield wall, preferably, a fitting portion is provided at each of the beam portion of the shield frame and the top surface portion of the shield cover, and the fitting portion provided at the beam portion of the shield frame and the fitting portion provided at the top surface portion of the shield cover are fitted to each other. According to this configuration, the beam portion of the shield frame is brought into tight contact with the top surface portion of the shield cover, and thus shielding by the predetermined part of the beam portion of the shield frame is achieved more effectively.

An electronic device according to a second aspect of the present invention includes the above-described circuit module according to the first aspect. According to this configuration, it is possible to suppress the occurrence of a defect (failure in mounting the shield member to the board) in the circuit module included in the electronic device.

### BRIEF DESCRIPTION OF THE DRAWINGS

FIG. 1 is a perspective view schematically showing a circuit module according to one embodiment of the present invention.

FIG. 2 is a plan view for illustrating a detailed structure of a shield frame that is one component of the circuit module shown in FIG. 1 (plan view showing a state where a frame portion of the shield frame is solder-joined to a mounting surface of a board).

FIG. 3 is a side view for illustrating the detailed structure of the shield frame that is one component of the circuit module shown in FIG. 1 (side view showing the state where the frame portion of the shield frame is solder-joined to the mounting surface of the board).

FIG. 4 is a plan view for illustrating a detailed structure of a shield cover that is one component of the circuit module shown in FIG. 1.

FIG. 5 is a side view for illustrating the detailed structure of the shield cover that is one component of the circuit module shown in FIG. 1 (side view showing fitting points between the shield frame and the shield cover).

FIG. 6 is a plan view of a region 100 circled by a broken line in FIG. 2 (plan view showing how wiring layers are routed in a solder joint part to which the frame portion of the shield frame is solder-joined).

FIG. 7 is a cross-sectional view taken along a line 200-200 in FIG. 2 (cross-sectional view showing a state where a predetermined part of a beam portion of the shield frame is used as a shield wall).

FIG. 8 is a block diagram for illustrating a configuration of an electronic device (terrestrial digital tuner) including the circuit module shown in FIG. 1.

FIG. 9 is a plan view for illustrating an experiment performed to confirm effects of the present invention (plan view of a shield cover of Comparative Example 1).

FIG. 10 is a plan view for illustrating the experiment performed to confirm the effects of the present invention (plan view of a shield cover of Comparative Example 2).

FIG. 11 is a graph for illustrating the experiment performed to confirm the effects of the present invention (graph showing a relationship between a temperature and a time in a reflow process).

### DETAILED DESCRIPTION OF PREFERRED EMBODIMENTS

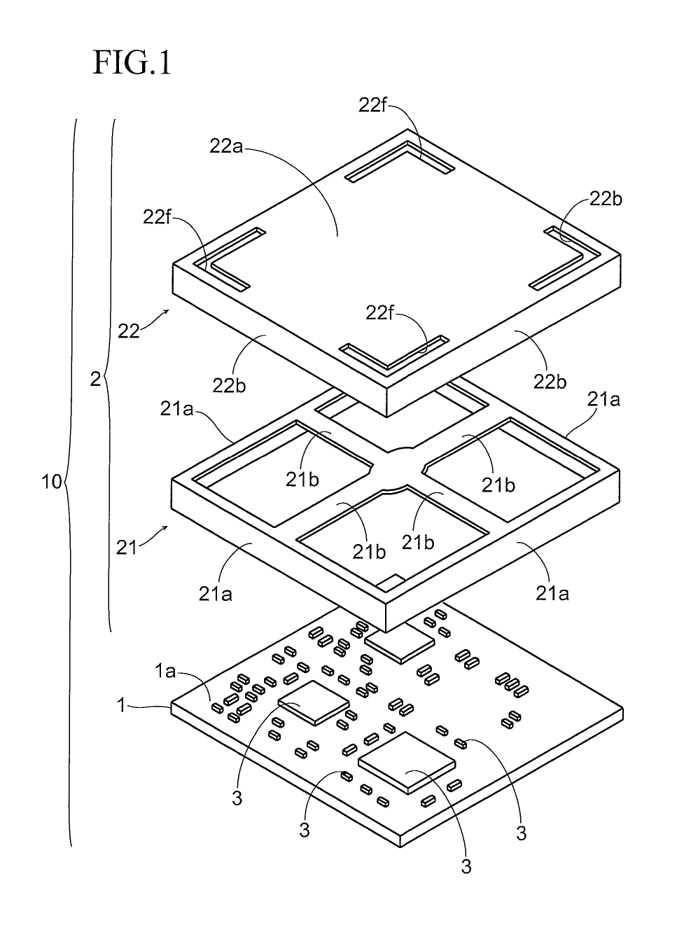

Hereinafter, a configuration of a circuit module 10 according to one embodiment of the present invention will be described with reference to FIGS. 1 to 7.

As shown in FIG. 1, the circuit module 10 of this embodiment is of a compact type to be built into various electronic devices and includes a multilayer wiring board 1 and a shield member 2. The multilayer wiring board 1 represents one example of the “board” of the present invention and is made of, for example, an organic board such as a glass epoxy board. Furthermore, the shield member 2 is made of, for example, a nickel silver plate (alloy plate of copper, zinc, and nickel).

The multilayer wiring board 1 has a mounting surface 1a with a wiring layer provided thereon and has a substantially quadrangular outer shape when seen in plan from the side of a region opposed to the mounting surface 1a (hereinafter, noted simply as “in plan”). Furthermore, a plurality of electronic components 3 are mounted on the mounting surface 1a of the multilayer wiring board 1, and transmission of an electric signal from an external device to any of the electronic components 3 (or transmission of an electric signal from the any of the electronic components 3 to the external device) is performed via the wiring layer. As the electronic components 3 mounted on the mounting surface 1a of the multilayer wiring board 1, an IC, a memory, a transistor, a resistor, and so on are used, and the number and types of the electronic components 3 are changed depending on the intended use. Furthermore, the electronic components 3 may be mounted by a method in which terminals thereof are soldered to the wiring layer or by a method in which the terminals thereof are inserted into through-holes and soldered in that state.

The shield member 2 is mounted to the multilayer wiring board 1, and thus the plurality of electronic components 3 mounted on the mounting surface 1a of the multilayer wiring board 1 are covered with the shield member 2.

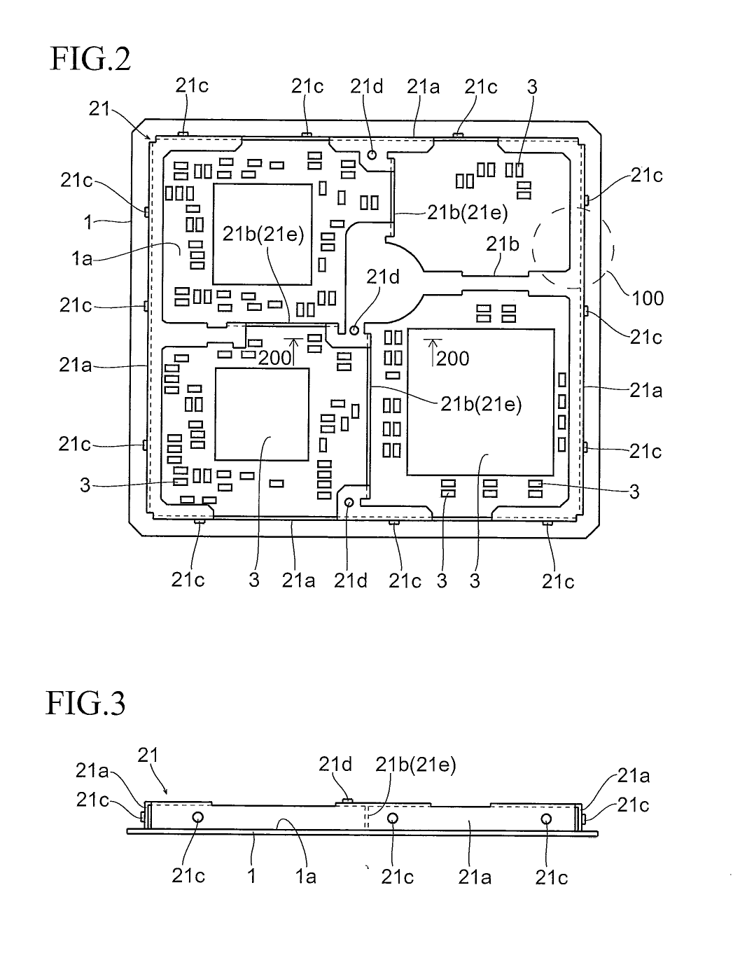

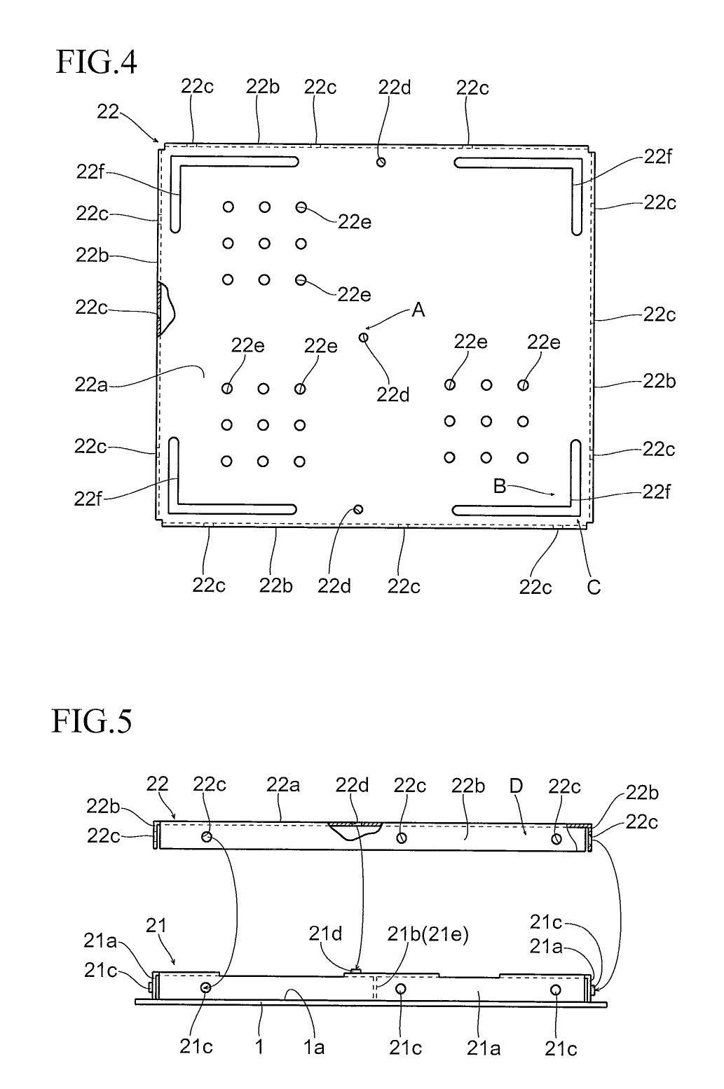

The shield member 2 includes a shield frame 21 and a shield cover 22 that are independent of each other. The shield frame 21 is attached to the multilayer wiring board 1, and the shield cover 22 is attached to the shield frame 21 so as to externally cover the shield frame 21, so that there is brought about a state where the shield member 2 is mounted to the multilayer wiring board 1. The shield frame 21 and the shield cover 22 are schematically shown in FIG. 1. FIGS. 2 and 3 show a detailed structure of the shield frame 21, and FIGS. 4 and 5 show a detailed structure of the shield cover 22.

As shown in FIGS. 2 and 3, the shield frame 21 has a frame portion 21a having a substantially quadrangular (frame-shaped) outer shape in plan and a substantially cross-shaped beam portion 21b provided in such a manner as to stride across a region enclosed by the frame portion 21a. That is, it can be said that the shield frame 21 is a skeleton structural body without a large-area plate-shaped portion (portion vulnerable to warping). The frame portion 21a of the shield frame 21 is solder-joined to the mounting surface 1a of the multilayer wiring board 1, so that there is brought about a state where the shield frame 21 is attached to the multilayer wiring board 1.

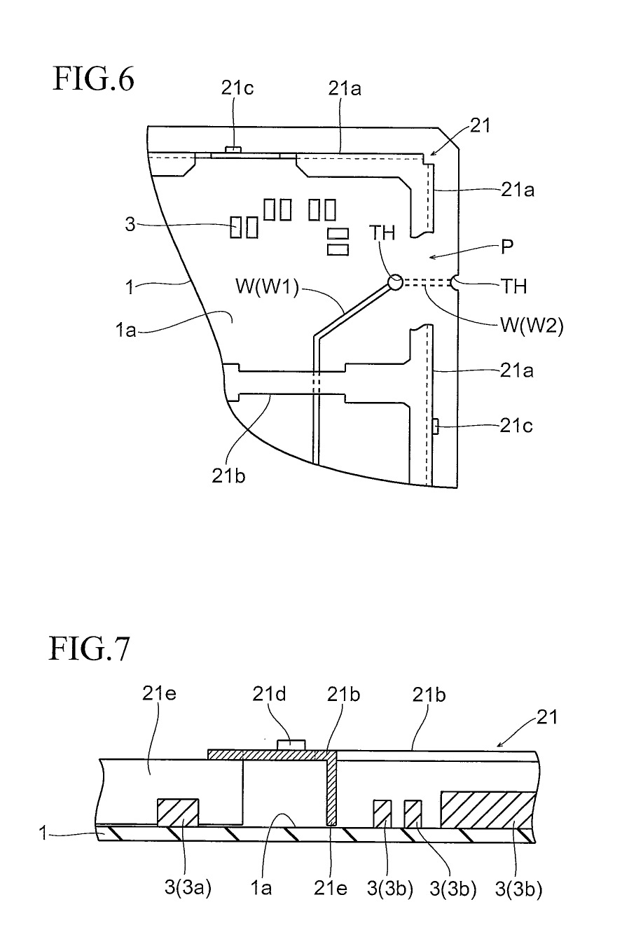

Now, as shown in FIG. 6, multiple wiring layers W are routed through the multilayer wiring board 1, and depending on the intended use, there may be a case where any of the wiring layers W is routed in such a manner as to traverse a solder joint part (part to which the frame portion 21a of the shield frame 21 is solder-joined) P.

In such a case, if, among the wiring layers W, an uppermost wiring layer (wiring layer provided on the mounting surface 1a of the multilayer wiring board 1) W1 is to traverse the solder joint part P, it is required that a cutout (opening) for routing the wiring layers W be formed at the frame portion 21a of the shield frame 21. This ends up decreasing an area usable for solder joining between the mounting surface 1a of the multilayer wiring board 1 and the frame portion 21a of the shield frame 21 by an amount defined by the width of the cutout formed at the frame portion 21a of the shield frame 21.

As a solution to this, in this embodiment, the uppermost wiring layer W1 is connected to a wiring layer W2 lying under the uppermost wiring layer W1 via a through-hole TH so that, instead of the uppermost wiring layer W1, the wiring layer W2 lying under the uppermost wiring layer W1 traverses the solder joint part P. That is, the wiring layers W are prevented from being exposed to the solder joint part P, and thus there is no need to form a cutout at the frame portion 21a of the shield frame 21. The frame portion 21a of the shield frame 21 is therefore solder-joined around the entire periphery thereof to the mounting surface 1a of the multilayer wiring board 1.

Referring back to FIGS. 2 and 3, at the frame portion 21a of the shield frame 21, a columnar fitting protrusion 21c is formed and is to be fitted into an after-mentioned fitting hole 22c formed at a side portion 22b of the shield cover 22. Furthermore, also at the beam portion 21b of the shield frame 21, a columnar fitting protrusion 21d is formed and is to be fitted into an after-mentioned fitting hole 22d formed at a top surface portion 22a of the shield cover 22. The fitting protrusions 21c and 21d each represent one example of the “fitting portion” of the present invention.

Moreover, a predetermined part 21e of the beam portion 21b of the shield frame 21 is bent so as to extend substantially perpendicularly toward the mounting surface 1a of the multilayer wiring board 1. As shown in FIG. 7, it therefore looks as if the predetermined part 21e of the beam portion 21b of the shield frame 21 were provided in such a manner as to stand like a wall within the plane of the mounting surface 1a of the multilayer wiring board 1. In this embodiment, the predetermined part 21e described above of the beam portion 21b of the shield frame 21 is made to function as a shield wall. To put this another way, when the electronic components 3 shown in FIG. 7 are classified into an electronic component 3a and an electronic component 3b, the electronic component 3a and the electronic component 3b are separated from each other by the predetermined part 21e of the beam portion 21b of the shield frame 21.

Referring next to FIGS. 4 and 5, the shield cover 22 has the top surface portion 22a having an substantially quadrangular outer shape in plan and the side portion 22b provided in a standing manner on the outer periphery of the top surface portion 22a. The fitting hole 22c having a circular opening shape is formed at the side portion 22b of the shield cover 22, and the fitting protrusion 21c at the frame portion 21a of the shield frame 21 is fitted into the fitting hole 22c at the side portion 22b of the shield cover 22. This allows the shield cover 22 to be attached to the shield frame 21. The fitting hole 22c formed at the side portion 22b of the shield cover 22 also represents one example of the “fitting portion” of the present invention.

The shield cover 22 is attached to the shield frame 21 merely by fitting the fitting protrusion 21c at the frame portion 21a of the shield frame 21 into the fitting hole 22c at the side portion 22b of the shield cover 22. Accordingly, disengaging the fitting between the fitting hole 22c at the side portion 22b of the shield cover 22 and the fitting protrusion 21c at the frame portion 21a of the shield frame 21 allows the shield cover 22 to be detached from the shield frame 21. That is, it can be said that the shield cover 22 is detachable from the shield frame 21.

Furthermore, the fitting hole 22d having a circular opening shape is formed at the top surface portion 22a of the shield cover 22. The fitting protrusion 21d at the beam portion 21b of the shield frame 21 is fitted into the fitting hole 22d at the top surface portion 22a of the shield cover 22, and thus the beam portion 21b of the shield frame 21 is brought into tight contact with the top surface portion 22a of the shield cover 22. The fitting hole 22d also represents one example of the “fitting portion” of the present invention.

With the beam portion 21b of the shield frame 21 being in tight contact with the top surface portion 22a of the shield cover 22 as described above, in a case where the predetermined part 21e of the beam portion 21b of the shield frame 21 is made to function as the shield wall (see FIG. 7), shielding between the electronic component 3a and the electronic component 3b is secured.

Furthermore, as shown in FIG. 4, a heat release hole 22e having a circular opening shape is formed at the top surface portion 22a of the shield cover 22. Thus, heat inside the shield cover 22 is released through the heat release hole 22e at the top surface portion 22a of the shield cover 22.

Moreover, in this embodiment, in addition to the fitting hole 22d and the heat release hole 22e, an L-shaped slit 22f is formed at the top surface portion 22a of the shield cover 22. The number of the L-shaped slits 22f formed at the top surface portion 22a of the shield cover 22 is four, and the four L-shaped slits 22f are arranged at four corners, in plan, of the top surface portion 22a of the shield cover 22, respectively. The L-shaped slits 22f at the top surface portion 22a of the shield cover 22 are each in a state of extending along two sides, in plan, of the top surface portion 22a of the shield cover 22.

With the above-described L-shaped slits 22f formed at the four corners, in plan, of the top surface portion 22a of the shield cover 22, respectively, and each of them being in the state of extending along two sides, in plan, of the top surface portion 22a of the shield cover 22, even if the shield cover 22 is heated, a temperature difference between the top surface portion 22a of the shield cover 22 and the side portion 22b thereof is prevented from becoming so large.

This was specifically confirmed in the following manner. That is, a shield cover having the same structure as that of the shield cover 22 shown in FIGS. 4 and 5 was fabricated and heated to 265° C. using a hot plate, and temperature measurement thereof was performed. Temperature values of this shield cover as measured at regions A to D in FIGS. 4 and 5 are shown in Table 1 below. For the sake of comparison, a shield cover having a structure obtained by omitting the L-shaped slit 22f from the structure of the shield cover 22 shown in FIGS. 4 and 5 was fabricated, and temperature measurement thereof was also performed under conditions similar to the above.

TABLE 1

| Measurement Point | Slit Provided | Slit Not Provided |
|---|---|---|
| Region A | 150° C. to 170° C. | 125° C. to 150° C. |
| Region B | 175° C. to 200° C. | 150° C. to 175° C. |
| Region C | 200° C. to 225° C. | |
| Region D | 200° C. to 225° C. | 200° C. to 225° C. |

Referring to Table 1, the shield cover with the slit and the shield cover without the slit were both at a temperature of 200° C. to 225° C. at their respective side portions (region D). On the other hand, the shield cover with the slit was at a temperature of 150° C. to 225° C. at its top surface portion (region A, region B, and region C), whereas the shield cover without the slit was at a temperature of 125° C. to 175° C. at its top surface portion (region A and region B).

Next, the following describes a method for manufacturing the circuit module 10 of this embodiment.

First, a solder paste is applied to the mounting surface 1a of the multilayer wiring board 1, and via the solder paste, the electronic components 3 and the shield frame 21 (frame portion 21a) are mounted on the mounting surface 1a of the multilayer wiring board 1. Then, using a reflow oven, the solder paste is melted and hardened. In this manner, the electronic components 3 are solder-joined to the mounting surface 1a of the multilayer wiring board 1, and the frame portion 21a of the shield frame 21 is solder-joined to the mounting surface 1a of the multilayer wiring board 1.

Subsequently, using an automatic tester or by visual inspection, it is checked whether or not there has occurred a mounting failure such as missing of any of the electronic components 3 or a short circuit. At this time, since the shield frame 21 is a skeleton structural body, this checking for a mounting failure is performed through interstices of a framework of the skeleton structural body.

After that, the fitting protrusion 21c at the frame portion 21a of the shield frame 21 is fitted into the fitting hole 22c at the side portion 22b of the shield cover 22, and thus the shield cover 22 is attached to the shield frame 21. At the same time, the fitting protrusion 21d at the beam portion 21b of the shield frame 21 is also fitted into the fitting hole 22d at the top surface portion 22a of the shield cover 22.

In this manner, the circuit module 10 of this embodiment is completed.

Using the reflow oven, the circuit module 10 is then solder-joined to another board (board commercially available to a user, etc.) to be built into various electronic devices.

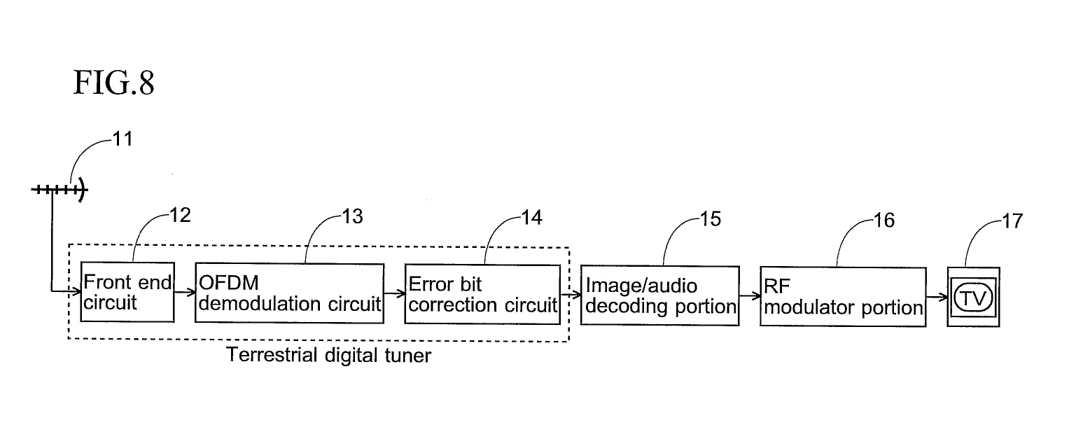

Examples of an electronic device in which the circuit module 10 of this embodiment is mounted include a terrestrial digital tuner that receives terrestrial digital broadcasts. A terrestrial digital tuner described here includes, as shown in FIG. 8, a front end circuit 12 that receives a signal transmitted from an antenna 11, an OFDM demodulation circuit 13, an error bit correction circuit 14, and so on. A signal outputted from the terrestrial digital tuner is transmitted to a display portion 17 via an image/audio decoding portion 15 and an RF modulator portion 16.

Furthermore, an electronic device in which the circuit module 10 of this embodiment is mounted may be a personal computer (encompassing a tablet-type terminal, etc.), a mobile telephone (encompassing a PHS, etc.), or the like, and needless to say, electronic devices other than these may also be adopted.

In this embodiment, using the above-described shield member 2 (member composed of the shield frame 21 and the shield cover 22), the frame portion 21a of the shield frame 21 is solder-joined to the mounting surface 1a of the multilayer wiring board 1, the shield cover 22 is disposed so as to externally cover the shield frame 21, and the side portion 22b of the shield cover 22 is attached to the frame portion 21a of the shield frame 21, so that there is brought about a state where the shield member 2 is mounted to the multilayer wiring board 1.

In this case, since the shield frame 21 is a skeleton structural body without a large-area plate-shaped portion (portion vulnerable to warping), even if the shield frame 21 is heated in a manufacturing process of the circuit module 10 (or a process of solder joining the circuit module 10 to another board), the shield frame 21 is hardly warped. Needless to say, it is also hardly likely that the shield frame 21 is warped after it is no longer heated (at the time the shield frame 21 is cooled).

Furthermore, since the L-shaped slit 22f is formed at a predetermined corner among the four corners of the top surface portion 22a of the shield cover 22 (at each of all the four corners in this embodiment) so as to extend along two sides forming the predetermined corner, even if the shield cover 22 is heated in the manufacturing process of the circuit module 10 (or a process of solder joining the circuit module 10 to another board), a temperature difference between the top surface portion 22a of the shield cover 22 and the side portion 22b thereof is prevented from becoming so large, so that warping of the shield cover 22 is suppressed to a reduced degree. This can prevent the shield cover 22 from remaining warped after it is no longer heated (at the time the shield cover 22 is cooled). Thus, even though the side portion 22b of the shield cover 22 is attached to the frame portion 21a of the shield frame 21, in no case is the frame portion 21a of the shield frame 21 subjected to a strong pulling force in a direction away from the mounting surface 1a of the multilayer wiring board 1.

Moreover, with the L-shaped slit 22f formed at a predetermined corner of the top surface portion 22a of the shield cover 22 so as to extend along two sides forming the predetermined corner, the top surface portion 22a of the shield cover 22 is made partially discontinuous with the side portion 22b of the shield cover 22. Thus, the following is also achieved. That is, even if the top surface portion 22a of the shield cover 22 is warped, the side portion 22b of the shield cover 22 (frame portion 21a of the shield frame 21 to which the side portion 22b of the shield cover 22 is attached) is prevented from floating under the influence of the warping of the top surface portion 22a of the shield cover 22.

As a result of the foregoing facts, a solder joint failure between the mounting surface 1a of the multilayer wiring board 1 and the frame portion 21a of the shield frame 21 can be avoided. That is, the shield member 2 can be securely mounted to the multilayer wiring board 1.

In addition to the above, this embodiment uses the above-described shield member 2 (member composed of the shield frame 21 and the shield cover 22) and thus eliminates the need to actually solder-join the shield cover 22 for covering the electronic components 3 to the multilayer wiring board 1. That is, even after the shield member 2 has been mounted to the multilayer wiring board 1, the shield cover 22 per se can be easily detached. Thus, for example, in a case where checking for a mounting failure such as missing of any of the electronic components 3 or a short circuit should be performed after the shield member 2 has been mounted to the multilayer wiring board 1, the checking for a mounting failure can be facilitated. Since the shield frame 21 is a skeleton structural body, the checking for a mounting failure can be performed through interstices of a framework of the skeleton structural body. Accordingly, there is no need to detach the shield frame 21 in this case.

Furthermore, in this embodiment, as described above, the fitting protrusion 21c is formed at the frame portion 21a of the shield frame 21, while the fitting hole 22c is formed at the side portion 22b of the shield cover 22, and the fitting protrusion 21c at the frame portion 21a of the shield frame 21 is fitted into the fitting hole 22c at the side portion 22b of the shield cover 22, so that there can be brought about a state where the shield cover 22 is securely attached to the shield frame 21.

Moreover, with the above-described method of attaching the shield cover 22 to the shield frame 21, it is only required to insert the fitting protrusion 21c at the frame portion 21a of the shield frame 21 into the fitting hole 22c at the side portion 22b of the shield cover 22, and thus an operation of attaching the shield cover 22 to the shield frame 21 is facilitated. Needless to say, an operation of detaching the shield cover 22 from the shield frame 21 is also facilitated.

Furthermore, in this embodiment, as described above, among the wiring layers W, instead of the uppermost wiring layer (wiring layer provided on the mounting surface 1a of the multilayer wiring board 1) W1, the wiring layer W2 lying under the uppermost wiring layer W1 traverses the solder joint part (part to which the frame portion 21a of the shield frame 21 is solder-joined) P, and thus there is no need to form a cutout (opening) for routing the wiring layers W at the frame portion 21a of the shield frame 21, so that the frame portion 21a of the shield frame 21 can be solder-joined around the entire periphery thereof to the mounting surface 1a of the multilayer wiring board 1. This reinforces the solder joint between the mounting surface 1a of the multilayer wiring board 1 and the frame portion 21a of the shield frame 21 and thus makes it even more unlikely that the shield frame 21 is warped.

Furthermore, in this embodiment, as described above, the beam portion 21b is provided in such a manner as to stride across a region enclosed by the frame portion 21a of the shield frame 21, and thus the shield frame 21 that is highly rigid and unlikely to be warped can be easily obtained.

Besides, the predetermined part 21e of the beam portion 21b of the shield frame 21 is made to extend toward the mounting surface 1a of the multilayer wiring board 1, and thus, without the need to separately prepare a member to be used as the shield wall, there can be brought about a state where the shield wall (predetermined part 21e of the beam portion 21b of the shield frame 21) stands within the plane of the mounting surface 1a of the multilayer wiring board 1.

Furthermore, in a case where the predetermined part 21e of the beam portion 21b of the shield frame 21 is made to function as the shield wall, the fitting protrusion 21d is formed at the beam portion 21b of the shield frame 21, while the fitting hole 22d is formed at the top surface portion 22a of the shield cover 22, and the fitting protrusion 21d at the beam portion 21b of the shield frame 21 is fitted into the fitting hole 22d at the top surface portion 22a of the shield cover 22. This brings the beam portion 21b of the shield frame 21 into tight contact with the top surface portion 22a of the shield cover 22, and thus shielding by the predetermined part 21e of the beam portion 21b of the shield frame 21 is achieved more effectively.

Next, the following describes an experiment performed to confirm the above-described effects.

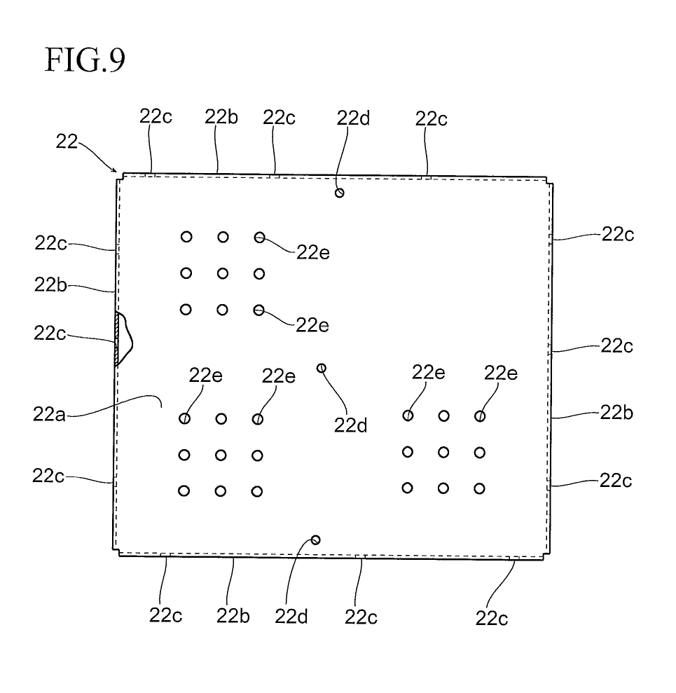

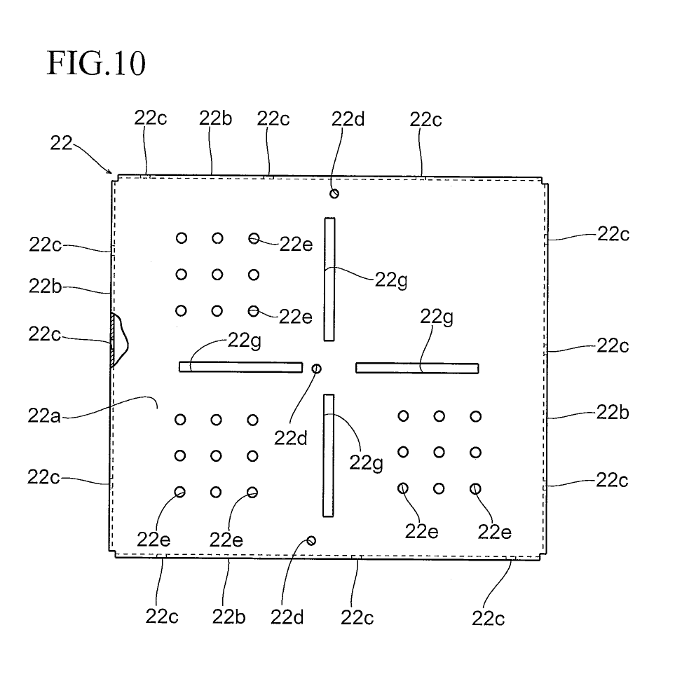

In this confirmation experiment, as Example, samples of a circuit module using a shield cover having the same structure as that of the shield cover 22 of the foregoing embodiment were fabricated (number of samples fabricated: 15). Furthermore, for the sake of comparison, as Comparative Example 1, samples of a circuit module were fabricated using a shield cover (see FIG. 9) having a structure obtained by omitting the L-shaped slit 22f from the structure of the shield cover 22 of the foregoing embodiment (number of samples fabricated: 61). Moreover, as Comparative Example 2, samples of a circuit module were fabricated using a shield cover (see FIG. 10) having a structure including, in the structure of the shield cover 22 of the foregoing embodiment, instead of the L-shaped slit 22f, four linear slits 22g arranged in a cross-shaped formation (number of samples fabricated: 10).

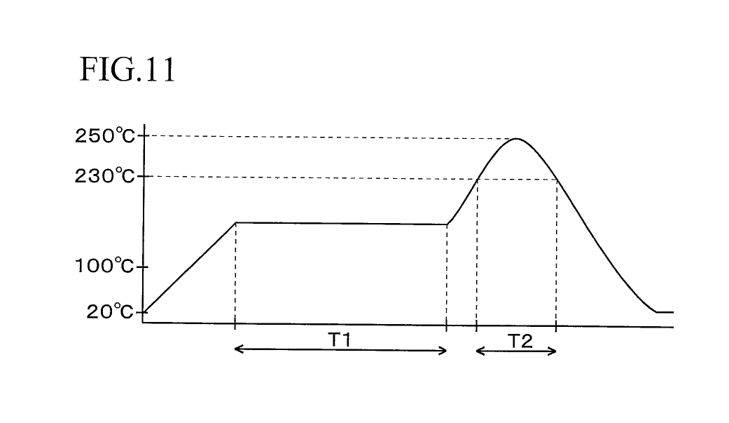

A reflow process in fabricating the circuit modules of these examples was performed under conditions shown in FIG. 11. To be more specific, a time period T1 indicates a preheating time period in which a heating time was set to 60 seconds to 120 seconds and a heating temperature was set to 130° C. to 180° C. Furthermore, a time period T2 indicates a full-scale heating time period in which a heating time was set to 30 seconds to 60 seconds and a heating temperature was set to 230° C. or higher. In this case, however, it was assumed that a peak temperature was 250° C. and a peak time was not more than 10 seconds.

With respect to Example, Comparative Example 1, and Comparative Example 2, it was checked whether or not the respective shield covers in the samples were warped, and results of the checking are as follows. That is, Example exhibited a 0% incidence of warping. On the other hand, Comparative Example 1 exhibited a 21.3% incidence of warping, with warping observed in 13 out of 61 samples. Furthermore, Comparative Example 2 exhibited an extremely high incidence as high as 40%, with warping observed in 4 out of 10 samples.

The embodiment disclosed herein is to be construed in all respects as illustrative and not limiting. The scope of the invention is indicated by the appended claims rather than by the foregoing description of the embodiment, and all changes that come within the meaning and range of equivalency of the claims are intended to be embraced therein.

For example, although in the foregoing embodiment, the L-shaped slit is formed at each of all the four corners of the top surface portion of the shield cover, the present invention is not limited thereto, and instead, the L-shaped slits (two L-shaped slits in total) may be formed at a diagonally opposed pair of corners among the four corners of the top surface portion of the shield cover, respectively. Alternatively, the L-shaped slit may be formed at only one corner among the four corners of the top surface portion of the shield cover, or the L-shaped slit may be formed at each of three corners among the four corners of the top surface portion of the shield cover.

What is claimed is:

1. A circuit module, comprising:
a board having a mounting surface on which an electronic component is mounted; and
a shield member that is mounted to the board so as to cover the electronic component,
wherein the shield member includes:
a shield frame having a frame portion that has a quadrangular outer shape when seen in plan from a side of a region opposed to the mounting surface and is solder-joined to the mounting surface; and
a shield cover that is disposed so as to externally cover the shield frame and has: a top surface portion having a quadrangular outer shape when seen in plan from the side of the region opposed to the mounting surface; and a side portion that is provided in a standing manner on an outer periphery of the top surface portion and is attached to the frame portion of the shield frame, and
when seen in plan from the side of the region opposed to the mounting surface, an L-shaped slit is formed at a predetermined corner among four corners of the top surface portion of the shield cover so as to extend along two sides forming the predetermined corner.

2. The circuit module according to claim 1, wherein
the L-shaped slit is formed at each of all the four corners of the top surface portion of the shield cover.

3. The circuit module according to claim 1, wherein
a fitting portion is provided at each of the frame portion of the shield frame and the side portion of the shield cover, and
the fitting portion provided at the frame portion of the shield frame and the fitting portion provided at the side portion of the shield cover are fitted to each other.

4. The circuit module according to claim 3, wherein
the fitting portion provided at the frame portion of the shield frame is a fitting protrusion, and the fitting portion provided at the side portion of the shield cover is a fitting hole.

5. The circuit module according to claim 1, wherein
the board is a multilayer wiring board, and
a predetermined wiring layer is present that is routed in such a manner as to traverse a solder joint part to which the frame portion of the shield frame is solder-joined, and instead of an uppermost wiring layer provided on the mounting surface, a wiring layer lying under the uppermost wiring layer is used as the predetermined wiring layer.

6. The circuit module according to claim 1, wherein
the shield frame further includes a beam portion that is provided in such a manner as to stride across a region enclosed by the frame portion of the shield frame.

7. The circuit module according to claim 6, wherein
a predetermined part of the beam portion of the shield frame is made to extend toward the mounting surface so as to stand within a plane of the mounting surface.

8. The circuit module according to claim 7, wherein
a fitting portion is provided at each of the beam portion of the shield frame and the top surface portion of the shield cover, and
the fitting portion provided at the beam portion of the shield frame and the fitting portion provided at the top surface portion of the shield cover are fitted to each other.

9. An electronic device comprising the circuit module according to claim 1.
